(19) United States
(12) Patent Application Publication
(10) Pub. No.: US 2024/0064905 A1
(43) Pub. Date: Feb. 22, 2024

(54) Exerting-Pressure Device and Electronic Apparatus Comprising the Same

(71) Applicants: TE Connectivity Solutions GmbH, Schaffhausen (CH); Tyco Electronics (Shanghai) Co., Ltd., Shanghai (CN)

(72) Inventors: Wei (David) Zhao, Shanghai (CN); Tingting Zhang, Shanghai (CN); Guoxiao (Neo) Shen, Shanghai (CN); Christopher Blackburn, Bothell, WA (US); Zhiqiang (Simon) Li, Shanghai (CN); Jiefeng (Lear) Zhang, Shanghai (CN)

(73) Assignees: TE Connectivity Solutions GmbH, Schaffhausen (CH); Tyco Electronics (Shanghai) Co., Ltd., Shanghai (CN)

(21) Appl. No.: 18/450,482

(22) Filed: Aug. 16, 2023

(30) Foreign Application Priority Data
Aug. 16, 2022 (CN) 202210982896.2

(51) Int. Cl. H05K 1/18; H05K 1/03; H05K 1/02

(52) U.S. Cl. CPC H05K 1/181; H05K 1/0306; H05K 1/0209; H05K 2201/10598; H05K 2201/10265

(57) ABSTRACT

A pressure-exerting device includes a first pressure-exerting unit adapted to press an electronic element on a circuit board. The first pressure-exerting unit has a pressure-exerting member defining a central opening sized to at least partially surround the electronic element, and a pressing elastic sheet arranged at an edge of the central opening of the pressure-exerting member and adapted to press the electronic element.

### CROSS-REFERENCE TO RELATED APPLICATIONS

This application claims the priority of Chinese Patent Application No. CN202210982896.2 filed on Aug. 16, 2022, the whole disclosure of which is incorporated herein by reference.

### FIELD OF THE INVENTION

The present disclosure relates to a pressure-exerting device and an electronic apparatus comprising the pressure-exerting device.

### BACKGROUND

An electronic element (e.g., an electronic chip) is typically pressed against a circuit board in an electronic apparatus, or a connector on the circuit board, by a pressure-exerting device to achieve electrical connection between the electronic element and the circuit board or the connector. The connection is achieved by bringing a pin of the electronic element into electrical contact with a contact of the circuit board or the connector. In the prior art, however, the pressure-exerting device applies too little pressure to a central region of the electronic element and of the circuit board or the connector. As a result, a mutual contact force between the pin in the central region of the electronic element and the corresponding contact in the central region of the circuit board or the connector is very small. This is particularly problematic with larger electronic elements or circuit boards. The contact in the central region of the circuit board is slightly deflected, thereby causing poor electrical contact between the pin in the central region of the electronic element and the corresponding contact in the central region of the circuit board or the connector, and further affecting the normal electrical connection between the electronic element and the circuit board or the connector. Furthermore, a heat dissipating plate for dissipating heat in an electronic apparatus is generally large and close to the electronic element. This impedes the pressure-exerting device from applying the pressure from a top side of the electronic element.

### SUMMARY

According to an embodiment of the present disclosure, a pressure-exerting device includes a first pressure-exerting unit adapted to press an electronic element on a circuit board. The first pressure-exerting unit has a pressure-exerting member defining a central opening sized to at least partially surround the electronic element, and a pressing elastic sheet arranged at an edge of the central opening of the pressure-exerting member and adapted to press the electronic element.

### BRIEF DESCRIPTION OF THE DRAWINGS

The invention will now be described by way of example with reference to the accompanying Figures, of which:

FIG. 1 is a perspective view of a pressure-exerting device according to an embodiment of the present disclosure.

FIG. 2 is a front view of the pressure-exerting device shown in FIG. 1.

FIG. 3 is a top perspective view of an electronic apparatus according to an embodiment of the present disclosure.

FIG. 4 is a top perspective view of the electronic apparatus shown in FIG. 3 with the heat dissipating plate removed.

FIG. 5 is a top perspective view of the electronic apparatus shown in FIG. 3 with the heat dissipating plate and the pressing plate removed.

FIG. 6 is a bottom view of the electronic apparatus shown in FIG. 3.

FIG. 7 is a cross-sectional view of the electronic apparatus taken along section C-C illustrated in FIG. 6.

FIG. 8 is a cross-sectional view of the electronic apparatus taken along section B-B illustrated in FIG. 3.

FIG. 9 is a cross-sectional view of the electronic apparatus taken along section A-A illustrated in FIG. 3.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An embodiment of the present disclosure includes a pressure-exerting device having a first pressure-exerting unit 10 for pressing an electronic element 21 on a circuit board 20. The first pressure-exerting unit 10 includes a pressure-exerting member 30 and a pressing elastic sheet 60. The pressure-exerting member 30 is provided with a central opening 303 and is positioned to at least partially contact and press the electronic element 21. The pressing elastic sheet 60 is provided at an edge of the central opening 303 of the pressure-exerting member 30, and is configured to press the electronic element 21.

In another aspect, the present disclosure includes a pressure-exerting device including the first pressure-exerting unit 10 for pressing the electronic element 21 on the circuit board 20, The first pressure-exerting unit 10 includes the pressure-exerting member 30, an elastic plate 40, and a connection member 50. The pressure-exerting member 30 is positioned to at least partially contact and press the electronic element 21. The elastic plate 40 is positioned on the other side of the circuit board 20 opposite to the pressure-exerting member 30. The connection member 50 is connected between the pressure-exerting member 30 and the elastic plate 40 to cause the elastic plate 40 to be deformed to generate an elastic force, which is transmitted to the pressure-exerting member 30 via the connection member 50 to cause the pressure-exerting member to press the electronic element 21.

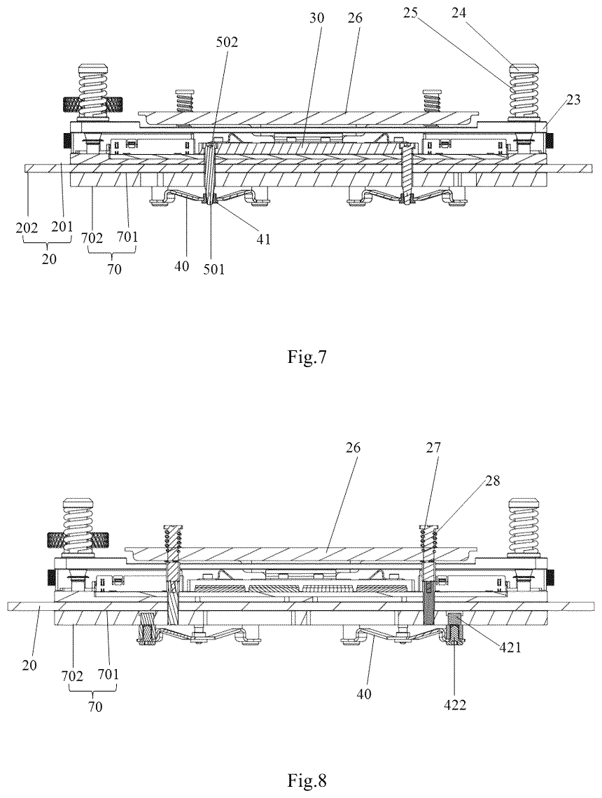

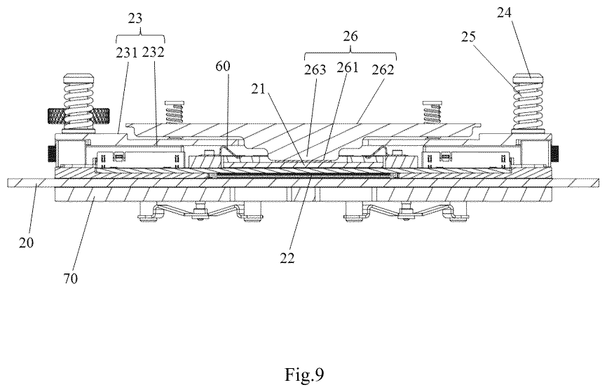

As best shown in FIGS. 7 and 9, the circuit board 20 has a first circuit board surface 201 and a second circuit board surface 202 opposite to each other, wherein the electronic element 21 is located on the first circuit board surface. A connector 22 may be arranged on the first circuit board surface 201 of the circuit board 20. The electronic element 21 may be pressed onto the connector 22 by the pressure-exerting device provided by the present disclosure, such that a stable electrical connection is established between the electronic element and the connector.

According to embodiments, the number of the elastic plates 40 may be one or more. The number of the connection members 50 may be equal to the number of the elastic plates 40 or a multiple of the number of the elastic plates 40. In other words, each of the elastic plates 40 may be connected to the pressure-exerting member 30 by one or more connection members 50.

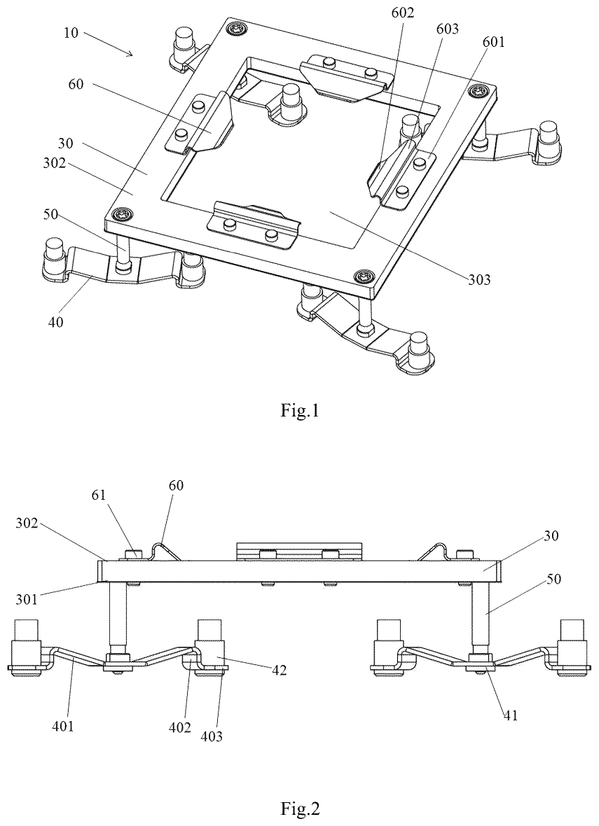

Referring to FIGS. 1 and 2, in some embodiments, the pressure-exerting member 30 has a first pressure-exerting member surface 301 and a second pressure-exerting member surface 302 opposite to each other, wherein the first pressure-exerting member surface 301 is adapted to at least partially contact and press the electronic element 21. Thus, the electronic element 21 is sandwiched between the first pressure-exerting member surface 301 of the pressure-exerting member 30 and the circuit board 20.

In the illustrated embodiment, the pressure-exerting member 30 is formed in a ring shape and has a central opening 303 in the central region thereof, so that the pressure-exerting member 30 is adapted to press a peripheral region of the electronic element 21. In particular, the pressure-exerting member 30 may be formed as a square or rectangular ring. In another embodiment, the pressure-exerting member 30 may be formed as a circular ring and other shapes adapted, or corresponding, to the electronic element 21.

As shown in FIGS. 1, 2 and 7, the first pressure-exerting unit 10 may further includes a nut 41 provided at an intermediate position of the elastic plate 40 and passing through the elastic plate 40. The connection member 50 has a threaded end 501 and a head 502 opposite to each other, wherein the head 502 is connected to the pressure-exerting member 30, and the threaded end 501 is adapted to be threadedly connected with the nut 41, so that the elastic plate 40 is in a state of elastic deformation to generate an elastic force when the nut 41 is tightened with the threaded end 501. In the illustrated embodiment, the head 502 of the connection member 50 is recessed in the pressure-exerting member 30, i.e., does not protrude beyond the second pressure-exerting member surface 302 of the pressure-exerting member.

As shown in FIGS. 2 and 7, the elastic plate 40 includes a body section 401 having elasticity, first fixing portions 403 located at opposite ends of the body section 401 in a length direction thereof, and first connection portions 402 connected between the body section 401 and the first fixing portions 403. In one embodiment, the elastic body section 401 is formed in an elongated shape, wherein the nut 41 is adapted to be secured in a central region of the body section 401. The body section 401 may be configured to be elastically deformed to generate the elastic force when the nut 41 is tightened with the threaded end 501 of the connection member 50.

The first fixing portion 403 is adapted to be fixedly positioned with respect to the circuit board 20. In the illustrated embodiment, a supporting plate 70 is provided on a side of the circuit board 20 opposite to the pressure-exerting member 30, and the first fixing portion 403 may be fixed to the supporting plate 70. However, in another embodiment, the first fixing portion 403 may be directly fixed to the circuit board 20.

The first connection portion 402 may have a winding or bent shape and curvingly extends between the body section 401 and the first fixing portion 403, so that the first fixing portion 403 is farther away from the circuit board 20 than the body section 401. Thus, when the body section 401 is in a tension state by tightening the nut 41 with the threaded end 501 of the connection member 50, the body section is elastically deformed to generate the elastic force.

With reference to FIG. 8, the optional supporting plate 70 supports the circuit board 20 on a side of the circuit board opposite to the pressure-exerting member 30. The supporting plate 70 has a first supporting plate surface 701 and a second supporting plate surface 702 opposite to each other. The first supporting plate surface 701 is adapted to support the circuit board 20. In one embodiment, the first fixing portions 403 at opposite ends of the elastic plate 40 are fixed to the supporting plate 70, preferably to the second supporting plate surface 702, by a fastening means 42.

In this embodiment, the circuit board 20 and the electronic element 21 thereon are sandwiched between the pressure-exerting member 30 and the supporting plate 70. When the elastic plate 40 is elastically deformed to generate the elastic force, the elastic force is transmitted between the pressure-exerting member 30 and the supporting plate 70 via the connection member 50. The pressure-exerting member 30 and the supporting plate 70 sandwich the circuit board 20 and the electronic element 21 thereon from a top side and a bottom side, respectively, thereby pressing the electronic element 21 against the circuit board 20.

Still referring to FIG. 8, the fastening means 42 includes a fixing member 421 and a screw 422. The fixing member 421 is adapted to be fixedly engaged with the supporting plate 70. The screw 422 is adapted to pass through the first fixing portion 403 of the elastic plate 40 so as to be threadedly connected with the fixing member 421.

In some embodiments, as best shown in FIGS. 1, 2 and 5, the first pressure-exerting unit 10 further includes the pressing elastic sheet 60 adapted to press the electronic element 21. Preferably, the elastic sheet 60 presses a central region of a top surface of the electronic element 21. In the illustrated embodiment, the pressing elastic sheet 60 is provided at the edge of the central opening 303 of the pressure-exerting member 30, particularly at the middle of four sides of the pressure-exerting member 30 in the form of a rectangular ring.

In one embodiment, the pressing elastic sheet 60 may include a second fixing portion 601, a pressing portion 602 and a second connection portion 603. The pressing elastic sheet 60 is fixed to the pressure-exerting member 30 via the second fixing portion 601. In the illustrated embodiment, the second fixing portion 601 may be detachably fixed to the second pressure-exerting member surface 302 of the pressure-exerting member 30 by a fastener, such as a screw 61. In another embodiment not shown, the second fixing portion 601 may be integrally formed with the pressure-exerting member 30.

In one embodiment, the pressing portion 602 may be configured to press the central region of the electronic element 21. In the illustrated embodiment, the pressing portion 602 is adapted to pass through the central opening 303 of the pressure-exerting member 30 to press the central region of the top surface of the electronic element 21. In one embodiment, an end of the pressing portion 602 is formed with a pressing surface parallel to the top surface of the electronic element 21, thereby increasing a contact area with the electronic element.

In one embodiment, the second connection portion 603 windingly or curvingly extends between the second fixing portion 601 and the pressing portion 602, and is configured to be elastically deformable to allow the pressing portion to press the electronic element 21. In one embodiment, the second connection portion 603 windingly extends from the second fixing portion 601 away from the second fixing portion 603, and then is bent and extends toward the central opening 303 of the pressure-exerting member 30.

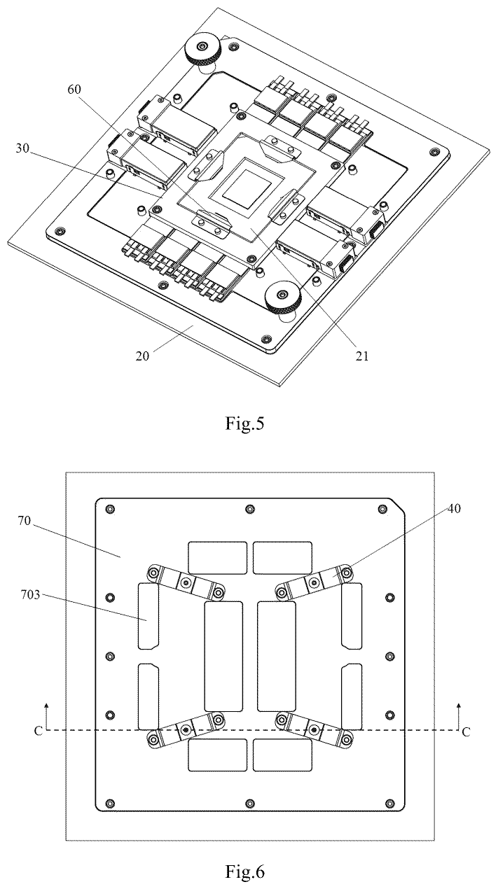

In some embodiments, as shown in FIG. 6, the supporting plate 70 is provided with a plurality of heat dissipating holes or heat sink holes 703. At least one of the heat dissipating holes is located correspondingly to the electronic element 21, i.e., on the other side of the circuit board 20 opposite to the electronic element 21, so as to dissipate heat from the electronic element.

With reference to FIGS. 4, 7 and 9, the pressure-exerting device further includes a second pressing unit for pressing the electronic element 21. The second pressing unit includes a pressing plate 23 that may be in contact with the pressing elastic sheet 60 so as to apply a pressure to the electronic element 21 through the pressing elastic sheet. As shown in FIG. 9, the pressing plate 23 may include a first pressing plate surface 231 and a second pressing plate surface 232 opposite to each other. The first pressing plate surface 231 is adapted to be in contact with the pressing elastic sheet 60, and preferably be in directly contact with the second connection portion 603 of the pressing elastic sheet. As a result, the first pressing plate 231 applies a pressure to the electronic element 21 by the pressing portion 602 of the pressing elastic sheet 60. In some embodiments, as shown in FIG. 4, a pressing plate opening 233 is formed in a central region of the pressing plate 23 to expose the electronic element 21.

With reference to FIGS. 7-9, the second pressure-exerting unit may further include a first bolt 24 and a first compression spring 25. In one embodiment, a shank of the first bolt 24 passes through the pressing plate 23 to be connected to the supporting plate 70 supporting the circuit board 20. The first compression spring 25 is arranged axially over a shank of the first bolt 24 and is sandwiched or compressed between a head of the first bolt 24 and the pressing plate 23, and preferably between the head of the first bolt and the second pressing plate surface 232. The number of the first bolt 24 and the first compression spring 25 of the second pressure-exerting unit may be one or more. In some embodiments, the combination of the first bolt 24 and the first compression spring 25 is positioned in the peripheral region of the pressing plate 23.

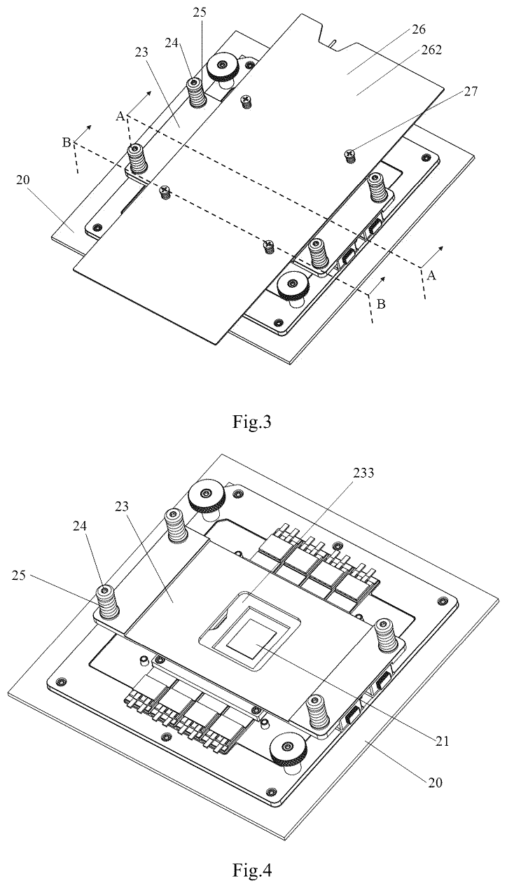

In some embodiments, as shown in FIGS. 3 and 9, the pressure-exerting device may further include a third pressure-exerting unit for pressing the electronic element 21. The third pressure-exerting unit includes a heat dissipating plate or heat sink plate 26 that is in contact with the electronic element 21 to press the electronic element and to dissipate heat from the electronic element. The heat dissipating plate 26 may include a first heat dissipating plate surface 261 and a second heat dissipating plate surface 262 opposite to each other. The first heat dissipating plate surface 261 is adapted to be in contact with the central region of the top surface of the electronic element 21 to press the electronic element and dissipate heat from the electronic element. In one embodiment, as shown in FIG. 9, a protrusion 263 is formed in a central region of the heat dissipating plate 26. The protrusion 263 protrudes toward the electronic element 21 and the central opening 303 of the pressure-exerting member 30 so as to be in contact with the central region of the top surface of the electronic element 21.

In some embodiments, as shown in FIGS. 3 and 8, the third pressure-exerting unit may further include a second bolt 27 and a second compression spring 28. A shank of the second bolt 27 passes through the heat dissipating plate 26 to be connected to the supporting plate 70 supporting the circuit board 20. The second compression spring 28 is axially fitted over the shank of the second bolt 27, and is sandwiched or compressed between a head of the second bolt 27 and the heat dissipating plate 26, preferably between the head of the second bolt 27 and the second heat dissipating plate surface 262. The number of the second bolt 27 and the second compression spring 28 of the third first pressure-exerting unit may be one or more.

An embodiment of the present disclosure further includes an electronic apparatus comprising the circuit board 20, the electronic element 21 located on the circuit board 20, and the pressure-exerting device according to the present disclosure, wherein the electronic element is pressed against the first circuit board surface 201 of the circuit board by the pressure-exerting device. The pressure-exerting device includes the first pressure-exerting unit 10 for pressing the electronic element 21, which includes the pressure-exerting member 30, the elastic plate 40 and the connection member 50. The pressure-exerting member 30 is positioned to at least partially contact and press the electronic element 21. The elastic plate 40 is positioned on the other side of the circuit board 20 opposite to the pressure-exerting member 30. The connection member 50 is connected between the pressure-exerting member 30 and the elastic plate 40 to cause the elastic plate to be deformed to generate an elastic force. The elastic force is transmitted to the pressure-exerting member 30 via the connection member 50 to cause the pressure-exerting member to press the electronic element 21. In some embodiments, the electronic element 21 includes a package to which the pressure-exerting device applies pressure so as to fixedly press the electronic element on the first circuit board surface 201.

According to the various embodiments of the present disclosure, the pressure-exerting device of the electronic apparatus exerts pressure not only to the periphery of the electronic element from a top side of the electronic element, but also to the central region of the electronic element, without impeding a heat dissipating plate from dissipating heat from the electronic element. Therefore, the electronic element is subjected to the more even pressure, thereby ensuring a normal electrical connection between the electronic element and the circuit board or the connector.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A pressure-exerting device, comprising:
a first pressure-exerting unit adapted to press an electronic element on a circuit board, including:
a pressure-exerting member defining a central opening sized to at least partially surround the electronic element; and
a pressing elastic sheet arranged at an edge of the central opening of the pressure-exerting member and adapted to press the electronic element.

2. The pressure-exerting device according to claim 1, wherein the first pressure-exerting unit further comprises:
an elastic plate adapted to be positioned on a side of the circuit board opposite to the pressure-exerting member; and
a connection member connected between the pressure-exerting member and the elastic plate, the connection member adapted to deform the elastic plate to generate an elastic force, the elastic force transmitted to the pressure-exerting member via the connection member for pressing the electronic element with the pressure-exerting member.

3. The pressure-exerting device according to claim 2, wherein the first pressure-exerting unit further comprises a nut provided at an intermediate position of the elastic plate, the connection member having a threaded end and an opposite head, the head being connected to the pressure-exerting member and the threaded end threadedly connected with the nut, the elastic plate is adapted to be elastically deformed to generate the elastic force when the nut is tightened on the threaded end of the connection member.

4. The pressure-exerting device according to claim 3, wherein the elastic plate comprises:
an elastic body section, the nut being secured in a central region of the body section;
first fixing portions located at opposite ends of the body section in a length direction thereof, and adapted to be fixedly positioned with respect to the circuit board; and
first connection portions curvingly extending between the body section and the first fixing portions, the first fixing portion is adapted to be positioned farther away from the circuit board than the body section, wherein the body section is adapted to be elastically deformed to generate the elastic force when the nut is tightened with the threaded end of the connection member.

5. The pressure-exerting device according to claim 4, further comprising a second pressing unit adapted to press the electronic element and including a pressing plate in contact with the pressing elastic sheet and adapted to exert a pressure to the electronic element through the pressing elastic sheet.

6. The pressure-exerting device according to claim 5, wherein a pressing plate opening is formed in a central region of the pressing plate to expose the electronic element therethrough.

7. The pressure-exerting device according to claim 5, wherein the second pressure-exerting unit further comprises:
a first bolt, a shank of the first bolt passing through the pressing plate and connected to a supporting plate adapted to support the circuit board on a side of the circuit board opposite to the pressure-exerting member; and
a first compression spring axially fitted over the shank of the first bolt and arranged between a head of the first bolt and the pressing plate.

8. The pressure-exerting device according claim 5, further comprising a third pressure-exerting unit adapted to press the electronic element and including a heat dissipating plate adapted to be in contact with the electronic element to press the electronic element and to dissipate heat from the electronic element.

9. The pressure-exerting device according to claim 8, wherein a protrusion is formed in a central region of the heat dissipating plate, the protrusion protruding toward the central opening of the pressure-exerting member and adapted to be in contact with the electronic element.

10. The pressure-exerting device according to claim 8, wherein the third pressure-exerting unit further comprises:
a bolt, a shank of the bolt passing through the heat dissipating plate to be connected to a supporting plate that supports the circuit board on a side of the circuit board opposite to the pressure-exerting member; and
a compression spring axially fitted over a shank of the bolt and arranged between a head of the second bolt and the heat dissipating plate.

11. The pressure-exerting device according to claim 2, wherein the first pressure-exerting unit further comprises a supporting plate adapted to support the circuit board on a side of the circuit board opposite to the pressure-exerting member, and opposite ends of the elastic plate are fixed to the supporting plate by a fastening assembly.

12. The pressure-exerting device according to claim 11, wherein the fastening assembly includes:
a fixing member adapted to be fixedly engaged with the supporting plate; and
a screw adapted to pass through the first fixing portion of the elastic plate to be threadedly connected with the fixing member.

13. The pressure-exerting device according to claim 11, wherein the supporting plate includes a plurality of heat dissipating holes, at least one of the plurality of heat dissipating holes positioned correspondingly to the electronic element so as to dissipate heat from the electronic element.

14. The pressure-exerting device according to claim 1, wherein the pressing elastic sheet comprises:
a fixing portion, the pressing elastic sheet being fixed to the pressure-exerting member via the fixing portion;
a pressing portion adapted to press a central region of the electronic element, and
a connection portion extending between the fixing portion and the pressing portion, and adapted to be elastically deformable to cause the pressing portion to press the electronic element.

15. The pressure-exerting device according to claim 14, wherein the pressing portion is adapted to pass through the central opening of the pressure-exerting member to press the central region of the electronic element.

16. The pressure-exerting device according to claim 14, wherein at least one of:
the fixing portion is detachably fixed to the edge of the central opening of the pressure-exerting member;
the second connection portion curvingly extends away from the fixing portion and toward the central opening of the pressure-exerting member; or
an end of the pressing portion is formed with a pressing surface arranged to be parallel to a top surface of the electronic element.

17. An electronic apparatus, comprising:
a circuit board;
an electronic element located on the circuit board; and
a pressure-exerting device having a first pressure-exerting unit adapted to press the electronic element against a first surface of the circuit board, including:
a pressure-exerting member defining a central opening at least partially surrounding the electronic element; and
a pressing elastic sheet provided at an edge of the central opening of the pressure-exerting member and pressing against the first surface of the electronic element.

18. The electronic apparatus according to claim 17, wherein the electronic element comprises a package to which the pressure-exerting device applies pressure to cause the electronic element to be fixedly pressed against the first surface of the circuit board.

19. The electronic apparatus according to claim 17, wherein a connector is provided on the circuit board, the pressure-exerting device pressing the electronic element against the connector.

20. The electronic apparatus according to claim 17, wherein the pressure-exerting device further comprises:
a second pressing unit pressing the electronic element and including a pressing plate in contact with the pressing elastic sheet and exerting a pressure on the electronic element through the pressing elastic sheet; and
a third pressure-exerting unit pressing the electronic element and including a heat dissipating plate in contact with the electronic element to press the electronic element and to dissipate heat from the electronic element.
